(19) United States
(12) Patent Application Publication
(10) Pub. No.: US 2005/0139250 A1
(43) Pub. Date: Jun. 30, 2005

(54) Thermoelectric devices and applications for the same

(75) Inventors: John G. DeSteese, Kennewick, WA (US); Larry C. Olsen, Richland, WA (US); John W. Johnston, Yakima, WA (US); Peter M. Martin, Kennewick, WA (US); Timothy J. Peters, Richland, WA (US)

Correspondence Address: KLARQUIST SPARKMAN, LLP, 121 SW SALMON STREET, SUITE 1600, ONE WORLD TRADE CENTER, PORTLAND, OR, 97204, US

(73) Assignee: Battelle Memorial Institute

(21) Appl. No.: 11/004,611

(22) Filed: Dec. 2, 2004

Related U.S. Application Data
(63) Continuation-in-part of application No. 10/726,744, filed on Dec. 2, 2003.
(60) Provisional application No. 60/558,298, filed on Mar. 30, 2004.

(51) Int. Cl. H01L 35/20; H01L 35/14; H01L 35/28

(52) U.S. Cl. 136/212

(57) ABSTRACT

High performance thin film thermoelectric couples and methods of making the same are disclosed. Such couples allow fabrication of at least microwatt to watt-level power supply devices operating at voltages greater than one volt even when activated by only small temperature differences.

### CROSS-REFERENCED TO RELATED APPLICATIONS

The present application is a continuation-in-part of copending U.S. patent application Ser. No. 10/726,744, filed Dec. 2, 2003, and claims the benefit of U.S. Provisional Patent Application No. 60/558,298, filed Mar. 30, 2004, both of which are hereby incorporated by reference.

### FIELD

The present disclosure relates to thermoelectric devices, materials and methods of making and using the same to produce efficient thermoelectric devices.

### BACKGROUND

The increasing use of portable electronics has driven research in the area of portable electric generators. Thermoelectric (TE) power sources have been found to be especially useful. TE power sources typically comprise three parts: a heat source, a heat sink, and a thermopile. The thermopile, consisting of a number of thermocouples connected in series, serves to convert some of the thermal energy into electrical energy. TE power sources generate electric power based on creating a thermal gradient across the thermocouples of the thermopile. The TE power source operates to convert the thermal energy to electric power by accepting thermal energy on a “hot” side or junction, passing it through the thermopile and rejecting heat to a “cold” side or junction.

Certain TE power sources and TE thermocouples in particular are formed using semiconductor materials. Semiconductor materials with dissimilar characteristics are connected electrically in series (to form thermocouples) and thermally in parallel, so that two junctions are created. The semiconductor materials are typically n-type and p-type. In a typical thermoelectric device, the electrically conductive connection is formed between the p-type and n-type semiconductor materials. These materials are so named because of their structure: the n-type has more electrons than necessary to complete a perfect molecular lattice structure while the p-type does not have enough electrons to complete a lattice structure. The extra electrons in the n-type material and the holes left in the p-type material are called “carriers.” The carriers are driven from the hot junction to the cold junction as a result of thermal diffusion resulting in an electrical current. For thermoelectric cooling, the electrons and holes transport heat as a result of imposed electrical current. Prior art FIG. 1a illustrates a form of such power conversion. Cooling action results from reversing the process.

A semiconductor TE device's performance is limited by the non-dimensional thermoelectric figure of merit (ZT) of the material, where T is the absolute temperature and Z is the thermoelectric figure of merit, Z=sa²/k (a-thermoelectric power, s-electrical conductivity, k-thermal conductivity). Typically TE devices are preferably formed of TE materials having relatively high thermoelectric figures of merit. In certain devices, however, the key objective is to produce power at voltages above 1.0 V in as small or compact a device as possible. The known TE materials having relatively high thermoelectric figures of merit cannot be deposited as thin films on substrates useful for forming small TE power source devices. Thus, although more efficient materials (i.e., materials with high ZT values) are typically better, for many applications it is more important that the resulting device be formed on a flexible substrate. As a result, although there may be some sacrifice of ZT value, using a TE material depositable on a substrate that allows fabrication of a small device with a relatively high voltage (without the need for a dc-dc converter) is better for certain applications. Unfortunately no such materials and methods are yet available.

Devices having ZT values of greater than 2.0 have been reported for Bi—Te/Sb—Te superlattices grown on single crystal GaAs. Such devices are not, however, suitable for many applications where hundreds or thousands of elements must be placed in a relatively small package.

Despite the potential and promise of TE devices, existing TE power sources have limited efficiency and electric potential when relatively small devices are made. Conventional semiconductor deposition techniques for making TE devices, such as electrochemical deposition, are not well suited for building optimally designed TE power sources. Difficult syntheses have limited the construction of many TE devices to bulk materials or minute quantities—each suffering from shortcomings in size or performance.

For example, currently available TE modules have structures similar to that depicted in prior art FIG. 1b, with each distinct thermoelement typically having a length and width on the order of a few millimeters. Such modules are described, for example, in U.S. Pat. No. 6,388,185 and C. B. Vining, Nature 413:577 (Oct. 11, 2001). These modules cannot provide voltages that readily match the input requirements of many devices, including power conditioning electronics.

A practical approach to building high-voltage, thin-film TE devices capable of microwatt power output in relatively small packages is needed. In addition, TE devices using a temperature gradient of about 10° C. or less would be helpful as well as TE devices operating at or near ambient temperatures. A number of applications require TE devices that operate at such temperatures and/or on such temperature gradients. For example, sensors used for building climate control or for other applications such as military applications where ambient energy is utilized if possible, operate on only 5 to 20° C. temperature differences.

In addition, in many circumstances, TE power sources and devices would be particularly useful in remote or inaccessible locations where hard-wired or battery-powered electrical energy sources are needed to operate particular devices. For example, remote sensors, such as might be used to measure temperature, pressure, humidity, the presence or movement of vehicles, humans and animals, or other environmental attributes, can easily be configured to acquire and transmit such data to a more accessible location. The conventional options available for providing power to such devices, such as batteries and solar cells, have drawbacks.

While battery technology has advanced tremendously in recent years, any device that draws electrical energy resulting from a chemical reaction has a useful life limited by the duration of the chemical reaction. Thus, remote applications relying exclusively on batteries are inherently limited by the battery life and reliability. Environmental factors can hinder the useful life of solar energy sources used in remote locations as well. Excessive cloud cover and shifting weather patterns can make solar cells unreliable. Dust and debris deposited on the surface of solar devices by rain or other weather related effects together with normal aging can also degrade the regular operation of these devices. Due to the drawbacks associated with these and other power technologies, there remains a need for reliable power sources that can operate over long time periods in remote locations.

Different constraints apply in non-remote settings. For example, in large buildings, tens of thousands of sensors could be usefully employed to provide smart sensing and control of energy delivery and distribution, as well as sensing and reporting of environmental conditions. At present, this vision is impractical because conventional power solutions are either technically inadequate or too expensive. Fitting every sensor with a battery power supply involves the above noted performance limitations of batteries in addition to the high cost of initial installation and periodic replacement. The alternative of hard wiring a large number of sensors to a central supply would improve reliability, but would necessarily involve complex circuitry and cost that make this approach economically unviable. These deficiencies of conventional solutions can be overcome by use of TE power sources such as TE power sources that produce electric power by harvesting and converting ambient energy in the manner provided by this disclosure.

One potential source of energy for the presently disclosed TE power sources and devices may be found in the differing temperatures that occur naturally in these remote, non-remote and less accessible locations, since thermoelectric devices can generate electric power in response to the existence of a temperature differential across the thermoelectric device. However, since the distances across conventional thermoelectric devices are typically small, heretofore none have been successfully configured to take advantage of the temperature variation between, for example, the ground below and the air above it.

### SUMMARY

A key parameter affecting the voltage produced by TE modules (also referred to herein as couples or thermocouples) is the length-to-area (L/A) ratio of the individual thermoelements, where A is the cross sectional area of a thermoelement. Current monolithic (or discrete element) modules are characterized by L/A values of less than about 20 cm⁻¹. Although some superlattice TE devices have been proposed that have L/A values that are much higher than the current monolithic devices, the superlattice TE devices suffer other shortcomings. Current superlattice TE devices have been proposed to comprise a n-type superlattice structure having alternating layers of 50 Å in thickness with individual n-type elements being about 0.0001 cm in total thickness. Although superlattice TEs are relatively efficient with relatively high Seebeck coefficients, there is no superlattice TE technology where films are depositable on flexible substrates. Currently, all superlattice materials are deposited on single crystals; the films are grown on GaAs substrates and then are removed and applied to another substrate. Thus, superlattice TEs are not typically useful for applications requiring small or compact TE devices.

Accordingly, disclosed are thin film thermoelectric (TE) modules and power sources. Certain embodiments of the disclosed thin film TE modules and power sources have relatively large L/A ratio values, greater than about 20 cm⁻¹ and perhaps more typically greater than about 100 cm⁻¹. Certain embodiments of the disclosed thin film TE modules and power sources have even larger L/A ratio values, for example up to about 1,000 to about 10,000 cm⁻¹ or greater. The L/A ratio values of certain embodiments of the disclosed TE power sources allow fabrication of μW to W power supplies providing voltages greater than 1 volt even when activated by relatively small temperature differences, such as 20° C. or 10° C., and certain embodiments even at temperature differences as small as about 5° C. The size of the disclosed TE power sources are relatively small—having volumes in the range of one to ten cm³—much smaller than existing devices that operate in the 1 μW to 1 W range, and certain embodiments provide voltages of greater than 1 V.

More specifically, the disclosed TE power sources comprise, in part, arrays of TE couples having multiple thermoelements (e.g., an n-type and a p-type thermoelement pair). The thermoelements are formed of sputter deposited thin films of BiₓTe_{y}, SbₓTe_{y} and BiₓSe_{y} alloys where x is typically about 2 and y is typically about 3. The thermoelements form the modules (thermocouples) for converting thermal energy to electrical energy. Such thermoelements typically comprise thin films of TE materials having L/A ratios greater than about 500 cm⁻¹. The devices include modules where thin films of p-type and n-type TE materials are deposited, e.g., on a suitable flexible substrate and are electrically connected to one another in series or in series-parallel.

Embodiments of the TE power sources comprise multiple TE modules, a heat source and a mechanism for removing heat. The TE power source may additionally include one or more ceramic plates or a ceramic-coated metallic shoe or the like as hot and cold junctions (connections).

Novel methods of constructing such TE elements, modules and devices, including sputter deposition of BiₓTe_{y}, SbₓTe_{y} and BiₓSe_{y} alloys (where x is typically about 2 and y is typically about 3) and the use of templates are also disclosed. The process may be used to deposit n-type and p-type films that exhibit useful TE properties. In addition, in certain embodiments, electrically conductive material connecting the thermoelements of the module are sputter deposited as well. When deposited onto flexible substrates, such films find many practical uses where a TE module of almost any configuration is required.

Certain embodiments of the TE power sources comprise a power source operable at ambient temperatures. Certain of the ambient energy operating TE power sources disclosed herein include embodiments of the disclosed thermocouple assembly (TE modules), a heat delivery member and a heat removal member (e.g., a low-temperature and a high-temperature heat pipe containing for example condensable fluids), and interfacing electronics including annular electronics, and power conditioning compartments. The heat delivery member and a heat removal member may be coupled to hot and cold junctions of the TE modules. One or both sides of the TE power source can be heated or cooled by other heat transport methods such as conduction, convection, and/or radiation. As such, these TE power sources can operate to produce electrical power in the range of 100 microwatts to 100 milliwatts, from small ambient differences in temperature (e.g., less than about 5° C., less than about 2° C., or less than about 1° C.). Further embodiments and descriptions are set forth throughout the specification and claims.

### BRIEF DESCRIPTION OF THE DRAWINGS

FIG. 1a is a representation of a prior art illustration of a basic approach to thermoelectric energy conversion.

FIG. 1b is a diagram showing a prior art arrangement of discrete TE elements.

FIG. 1c is a representation illustrating the L/A ratio parameters for a single prior art TE element as shown in the device of FIG. 1b.

FIG. 2a illustrates a portion of an embodiment of the disclosed n-type/p-type TE thin film modules.

FIG. 2b illustrates the L/A ratio parameters for a single p-type thin film TE element of the embodiment of the module illustrated in FIG. 2a.

FIG. 3 illustrates a portion of an embodiment of the disclosed n-type/p-type TE thin film modules.

FIG. 4 illustrates an embodiment of the disclosed TE power source.

FIG. 5 illustrates an embodiment the disclosed TE power source in which TE thin film modules, such as those illustrated by FIG. 6, are wound about a spindle.

FIG. 6 illustrates an embodiment of the disclosed n-type/p-type TE thin film modules as deposited on a flexible substrate.

FIG. 7 illustrates an embodiment of the disclosed power source wherein arrays of TE thin film modules, such as those of FIG. 2a, FIG. 3, FIG. 6 or modules with relatively wider thermoelements are folded in an accordion configuration.

FIG. 8 illustrates an embodiment of the disclosed power source device wherein a nuclear heat source is positioned between arrays of TE thin film modules folded in an accordion configuration.

FIG. 9a is an illustration of disclosed n-type and p-type TE thin film modules deposited in an array configuration on a substrate, with representative dimensions for the same.

FIG. 9b illustrates representative dimensions of thermoelements in the embodiment of the TE thin film modules depicted in FIG. 9a.

FIG. 10 illustrates a TE sensor that uses heat from one side of the thermopile.

FIG. 11 is a graph showing the dependence of the Seebeck coefficient and electrical conductivity of TE materials deposited on a KAPTON substrate, on sputter deposition conditions.

FIG. 12a is a photograph of a representative mask suitable for use in depositing n-type thermoelements in the configuration shown in the embodiments of the TE modules of FIG. 2a and FIG. 6.

FIG. 12b is a photograph of a representative mask suitable for use in depositing p-type thermoelements in the configuration shown in the embodiments of the TE modules of FIG. 2a and FIG. 6.

FIG. 12c is a photograph of a representative mask suitable for use in depositing conducting connectors in the configuration shown in the embodiments of the TE modules of FIG. 2a and FIG. 6.

FIG. 13 is a photograph of disclosed n-type and p-type TE thin film modules deposited on a flexible substrate.

FIG. 14 shows an embodiment of the disclosed n-type and p-type TE thin films deposited on a flexible substrate wherein the n-type and p-type TE thin films are connected in a series-parallel arrangement.

FIG. 15 shows an embodiment of the disclosed TE power source.

FIG. 16 is a block diagram showing an embodiment of the disclosed TE power source in a sensor system.

FIG. 17 is a graph of supercapicitor voltage plotted against time measured using the embodiment shown as Configuration a, of FIG. 16.

### DETAILED DESCRIPTION

Disclosed are TE modules comprising pairs of sputter deposited thin film thermoelements and electrically conductive members connecting the thermoelements to one another in series or in series-parallel. Also disclosed are TE power source devices formed of multiple TE couples such as arrays of TE couples wherein the thin film thermoelements have an L/A ratio of greater than at least about 20 cm⁻¹ or greater than about 100 cm⁻¹ with certain embodiments having an L/A ratio of greater than 1000, 10,000 and even higher.

Unless otherwise indicated, all numbers expressing quantities of ingredients, properties such as L and A values, thicknesses, power levels, and so forth used in the specification and claims are to be understood as being modified by the term “about” whether explicitly stated or not. Accordingly, unless indicated clearly to the contrary, the numerical parameters set forth are approximations.

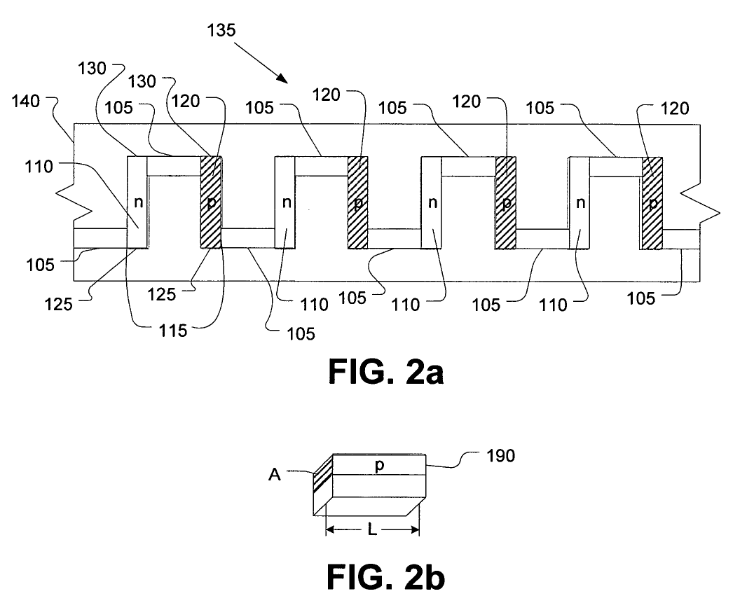

One embodiment of multiple thin film TE modules 115 utilized to form the disclosed TE power source 100 (see e.g., FIG. 4) is shown in FIG. 2a. FIG. 2a depicts a portion 135 of the TE power source 100, the portion 135 comprising the multiple TE modules 115 formed on a substrate 140. The TE modules 115 comprise pairs of n-type thermoelements 110 and p-type thermoelements 120 formed of semiconductor thin films.

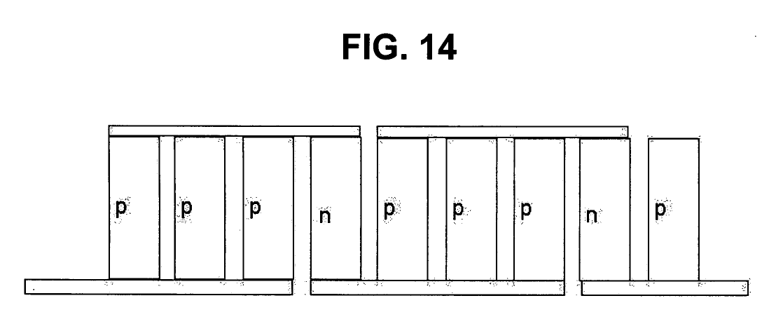

Alternating n-type and p-type thermoelements 110, 120 of the TE modules 115 may be positioned parallel to one another as shown in FIG. 2a, in series-parallel as shown in FIG. 14, or may be placed in other suitable fashions (as mentioned below). Electrical connection (through electrically conductive member 105) of one n-type thermoelement 110 with one p-type element 120 forms a complete, single TE module 115 (also referred to as a thermocouple or a couple). Electrically conductive members 105 connect the n-type thermoelements 110 to p-type thermoelements 120, for example, alternately at adjacent thermoelement first ends 125 and adjacent thermoelement second ends 130 (as shown in FIG. 2a).

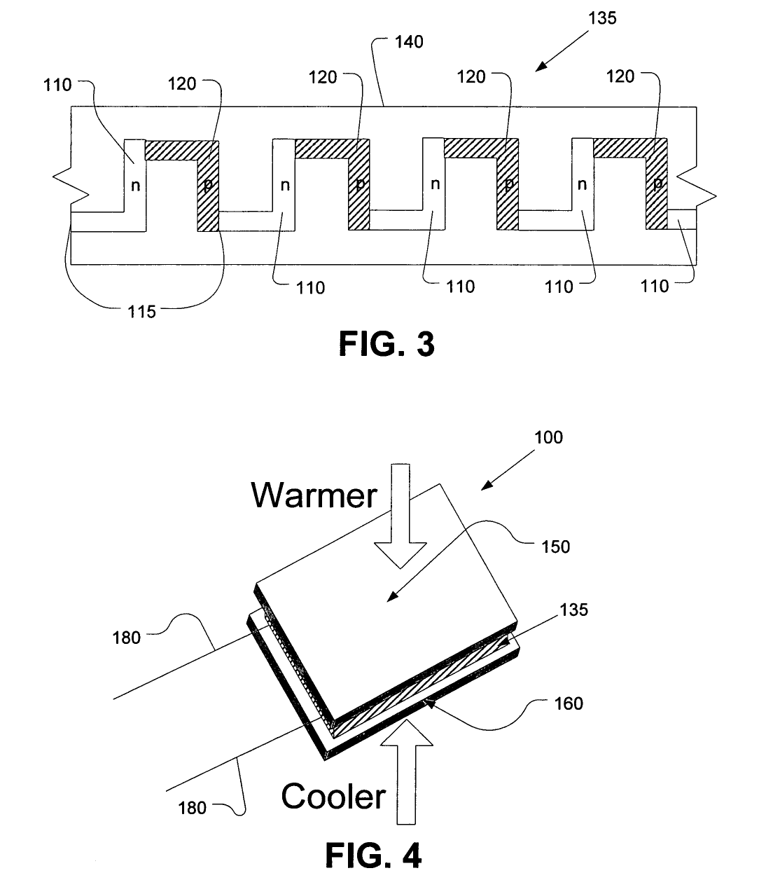

The electrically conductive members 105 may be substantially perpendicular to the elements 110, 120 or may be positioned in any suitable manner so as to electrically connect the thermoelements in series or in series parallel. In another possible configuration, there may be no separate electrically conductive members but instead the TE p-type and n-type alternating elements may be connected directly to one another, as for example shown in FIG. 3. Such a device would reduce the number of deposition steps required to form the TE module. For example, in another embodiment the n-type and/or p-type materials may be placed at angles to one another, connecting at alternating ends so that they come together at the hot and cold ends—forming a zigzag type configuration. In another possible alternative embodiment electrically conductive members are formed of the n-type or p-type elements themselves and are positioned as shown in FIG. 3. Clearly the individual TE elements and the array of TE elements making up a module may take a myriad of configurations.

The TE modules 115 may be formed on a flexible or a rigid substrate 140.

A TE power source 100 may include any number of TE couples 115 depending upon the application of the power source. Certain TE power sources comprise, e.g., from about 500 to 2000 TE modules 115. As a specific example application, a TE power source 100 used to power a temperature sensor or used to power a wireless transmitting device, with a power of 50 μW at 1.0 V, might utilize 600 to 800 n-p thermocouples (TE modules 115) with each TE element being about 1 cm long, 0.1 cm wide and 0.0001 cm in thickness. A nuclear TE power source designed to provide 100 mW at 1.0 V would potentially involve the same number of thermocouples, but the elements would more likely be about 0.2 cm in length, 1 cm wide and 0.0040 cm in thickness. The voltage required of the TE power source determines the number of thermocouples (TE modules) necessary and the desirable current determines the necessary L/A ratio of the thermoelements.

Possible embodiments of a complete TE power source 100 are shown in FIGS. 4, 7 and 8. In addition to the array of TE modules 135, the TE power source may comprise thermally conductive plates 150, 160, such as ceramic plates on the upper and lower edges of the substrate 140 (as shown in FIG. 4), a single ceramic plate, a ceramic shoe or other suitable enclosure devices. Electrical leads 180 are connected to the array of TE couples 135 of the TE device 100 to receive and transmit the electrical energy produced by the device.

The embodiment of the thin film TE power source 100 may further comprise a hot junction (or heat source) and a cold junction. The hot junction or heat source may comprise any suitable source depending upon the application of the device, for example a chemical energy source, heat from the environment, or a nuclear heat source as shown in FIG. 8. The cold junction may comprise any suitable heat removal mechanism constructed or positioned in a manner that allows heat to be relieved from or extracted from the TE power source. For example, the cold junction may comprise a heat pipe arrangement or exposure to the environment by, e.g., convection cooling.

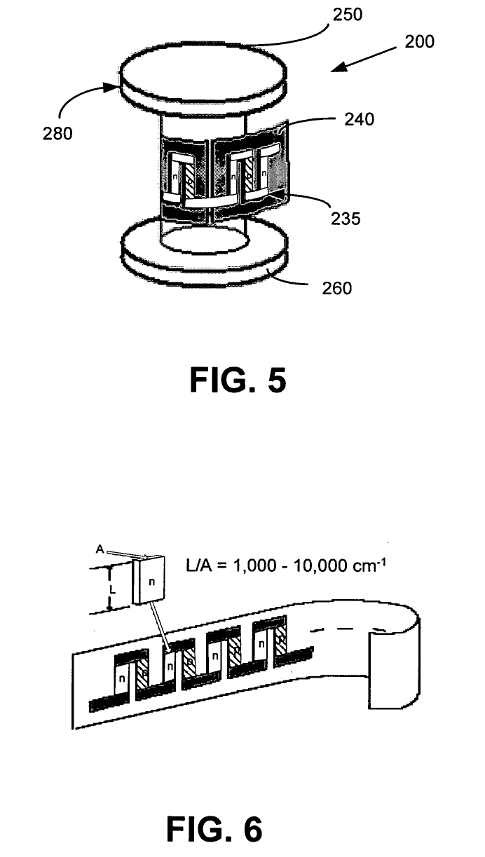

In another particular embodiment the TE power source 200 comprises multiple TE couples forming an array of modules 235 deposited onto a flexible substrate 240 (FIG. 5). The array of couples 235 is wound in a coil like fashion and positioned between hot and cold junctions 250 and 260. The array module 235 may simply form a coil or may be wound about an apparatus such as a spindle 280. Such a configuration provides an even smaller TE power source without sacrificing power output.

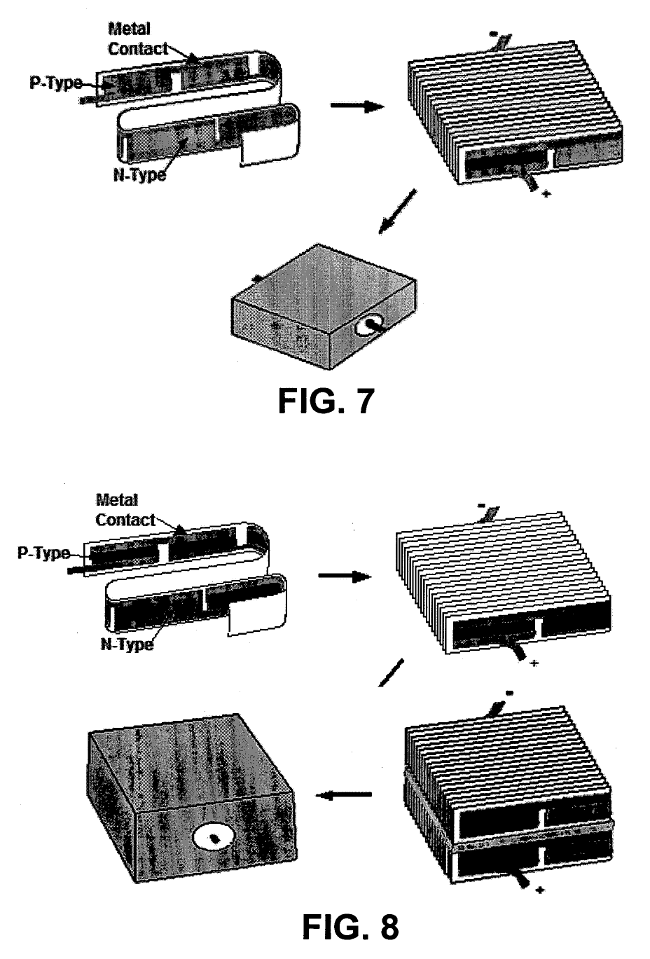

If a TE power source application requires relatively large currents, the internal resistance of the TE array is preferably made to be relatively low. To do so may involve forming thermoelement films that have relatively low values of L/A. To create films with lower L/A values, relatively wide thermoelements may be deposited and used. The TE power source depicted in FIGS. 7 and 8 may utilize thin film thermoelements having relatively large widths deposited on a flexible substrate such as polyimide tape. The TE module array may then be configured in an accordion-like arrangement and packaged with appropriate feedthroughs, as shown in FIGS. 7 and 8.

The current density of TE power sources as disclosed herein will depend on the total number of thermoelements, and the L and A values for the thermoelements. Put another way, if particular current densities are desirable for a particular TE power source, the number of thermoelements and L and A values may be manipulated to meet such requirements. Referring to an embodiment configured as shown in FIG. 3, if the thermoelements were deposited to have an L value of 1 cm, a width of 0.1 cm and a film thickness of 0.0001 cm, a TE power source based on about 500 of such thermoelements would produce 10 micro amps, whereas with wider thermoelements such as discussed in relation to and illustrated in FIGS. 7 and 8, a current of 100 milliamps could be produced. With either such embodiments, a current density of about 1 Amp/cm² would flow.

### Thin Film TE Thermoelements

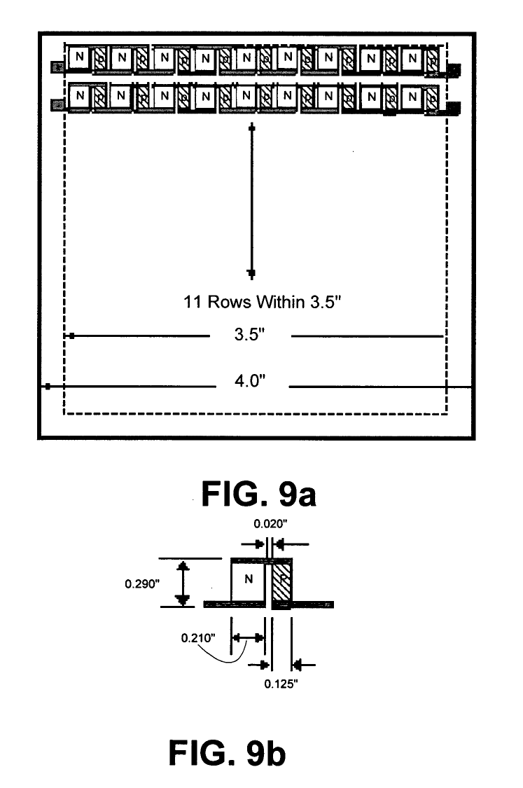

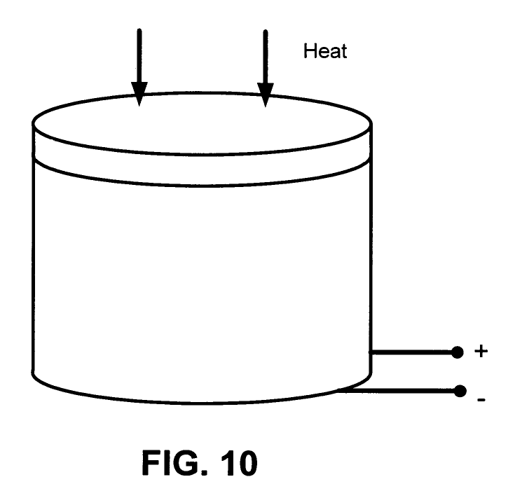

The TE thermoelements, although depicted in most of the figures as rectangular in shape, may take any suitable shape. Clearly, with rectangular-shaped thermoelements the dimensions may also be varied depending upon the ultimate application of the resulting TE power source being fabricated. For example, the dimensions of the individual thermoelements length, width, and thickness as well as the number of elements and the array configuration may all be changed (see, e.g., FIGS. 9a and 9b). The resistivity of the n-type and p-type materials may be different, so if one desires to minimize the total resistance, the L/A ratios can be manipulated. In addition, the p-type thermoelements may have different dimensions, such as different widths, than those dimensions of the n-type elements. Furthermore, for thermoelements of widths too great to be easily folded or coiled on a flexible substrate, the thermoelements may be broken up into separate pieces positioned in parallel to one another and in series with the opposite type thermoelements, such as, for example, the configuration shown in FIG. 14 (i.e., in series-parallel configurations).

One group of thermoelectric materials for power generation in the 0° C. to the 100° C. temperature range are semiconductors and related alloys based on BiₓTe_{y}, SbₓTe_{y} and BiₓSe_{y} where x is typically about 2 and y is typically about 3. The values of x and y may vary depending upon the power supplied to the sputter deposition targets (or equivalently the flux coming from each target). Such thin film thermoelement materials can be sputtered onto a variety of substrates, such as very useful flexible substrates (e.g., polyimide films such as those currently manufactured by the DuPont Corporation under the KAPTON trademark) which allow for fabricating very compact TE power sources.

The films forming the thermoelements 110, 120 may vary in thickness, but certain embodiments of the disclosed TE devices include thermoelements having thicknesses of at least 0.1 mm. The desirable thickness depends on the ultimate application of the TE power source being fabricated. In addition, the thickness variation will depend on the sputtering system arrangement, but typically fall within ±5%.

The thermoelements 110, 120 may vary in area but certain embodiments of the disclosed TE devices include thermoelements having an L/A ratio of greater than about 50 cm⁻¹. Of course, as mentioned above, the L and A values and/or other dimensions of the thermoelements may be varied as desired according to the desired application of the resulting TE device. The range for the L, A and thickness values depend on the power requirements of the ultimate TE power source being made. If it is desirable to have a power source having a voltage of 1.0 or 2.0 volts, then the choice of L/A values depends on the current requirements. For example, in the first two specific embodiments described above, the L/A value for a TE power source for a sensor is 100,000 and for a nuclear battery the L/A ratio is 50. The third specific embodiment involves an array of TE thermoelement modules having an L/A value about in the range of prior art discrete elements.

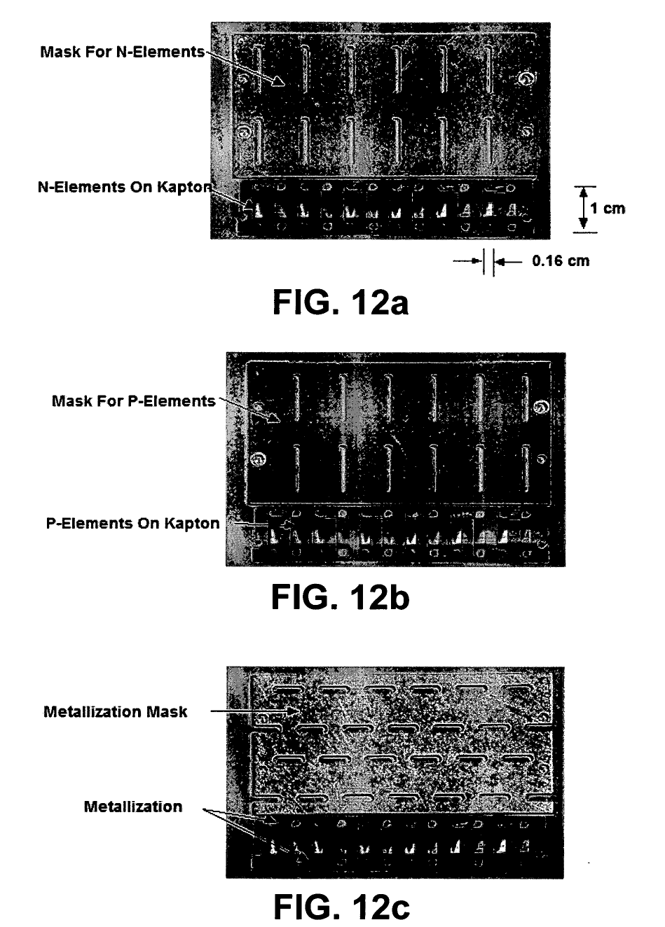

An advantage of the present methods for fabricating TE thermoelements is that the thermoelements are being sputter deposited and thus are more controllable and easily manipulated than are thermoelements made by standard approaches involving the growth of crystalline boules followed by cutting. Such prior approaches to defining the thermoelement L/A ratios are impractical on a small scale, let alone on a commercial scale. The templates used in the deposition of the thermoelement thin films are simply varied accordingly; see, for example, FIGS. 12a-12c.

Sputter deposited thin films based on superlattice structures can also be used to fabricate the thermoelectric power sources. Each n-type and p-type film could consist of a multilayer film structure with the individual layers being approximately 10 Å to 200 Å thick, and the total film thickness varying as described for the homogeneous films described herein. For example, and not meant to be limiting, a n-type superlattice film might consist of alternating Bi₂Te₃ and Sb₂ Te₃ layers with thicknesses of 50 Å and 150 Å, respectively, which are deposited at ambient conditions. A p-type superlattice structure may involve a similar structure, but grown with a different substrate temperature. These film structures can have larger values of electrical conductivity and Seebeck coefficient, and lower values of thermal conductivity, all of which allow improved power source efficiency.

### Substrate Materials

In certain embodiments, the p-type and n-type TE thermoelements are deposited onto a flexible substrate. The flexible substrate may be, e.g., a polyimide, such as KAPTON, however, any suitable flexible substrate may be used. The substrate should be able to withstand sputter deposition conditions without undue deterioration. In other embodiments TE materials are deposited on a substrate comprising any suitable sufficiently rigid substrate (e.g., glass or other electrically insulating materials that possess relatively low thermal conductivities). Essentially any electrically insulating substrate 140 (FIG. 2a) (or substrate coated with an insulating material) may be utilized for the rigid or flexible TE device as long as the substrate can withstand the deposition conditions and can meet required thermal conductivity levels.

### Electrically Conductive Members

As discussed above, TE modules are formed by electrically connecting a thin film n-type thermoelement to a p-type thermoelement through electrically conductive members. The electrically conductive members may comprise any suitable electrically conductive material. For example, the electrically conductive members may comprise a metal, such as aluminum, gold, nickel, and mixtures thereof. In one particular embodiment the conductive members comprise a nickel layer formed on the substrate and a gold layer formed on the nickel layer

### Methods for Constructing Thin Film TE Elements

TE thin film thermoelements and TE modules are formed by sputter deposition. In particular embodiments a mask or template is used as shown in FIGS. 12a-12c. The masks may be formed by standard lithography and/or etching techniques to control the shape and position of each TE thermoelement and conductive member on a substrate.

The disclosed process allows for the deposition of many (e.g., hundreds, thousands, or more) TE thermoelement couples on flexible materials such as KAPTON polyimide (available from DuPont). A representative individual p-type TE thermoelement 190 is shown in FIG. 2b, which also illustrates the L/A ratio. High voltage, μW to mW (or greater, e.g., W) TE power sources comprising hundreds or thousands of TE modules can be made with the disclosed process.

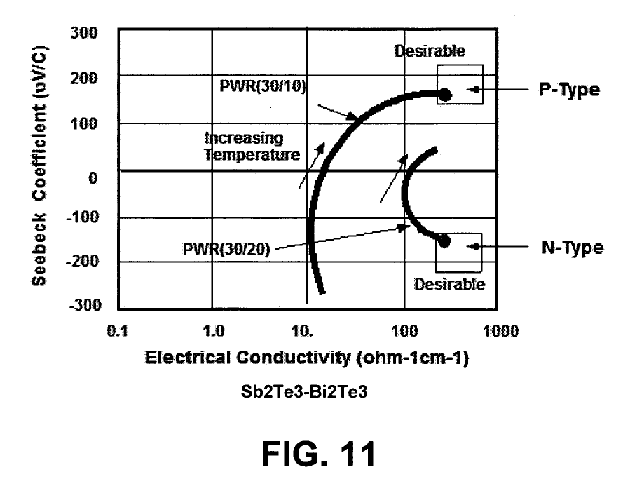

With reference to FIG. 11 and Table 1 below, a wide range of sputter deposition process parameters were used to obtain TE thermoelement materials having desirable properties. In particular, a myriad of sputtering gas pressures, target powers, deposition rates, target-substrate distances and substrate temperatures were tested. Certain exemplary sputter deposition methods are specifically disclosed below but clearly other sputter deposition parameters may produce suitable thin films for forming the TE thermoelements disclosed herein.

The thin films forming the TE elements may be sputter deposited using, for example, RF magnetron sputtering. The films may be deposited simultaneously from two of three possible sources, for example, and not meant to be limiting, Bi₂Te₃, Sb₂Te₃ and Bi₂Se₃ alloys, or combinations thereof. The amount of RF power supplied to each of the targets, substrate temperature and sputtering gas pressure are varied for deposition conditions that result in films with desired properties which in turn depend upon the application of the device. Representative thin film material parameters and sputtering conditions are shown in FIG. 11. The specific examples given below are not to be considered limiting of the present disclosure but merely representative.

### EXAMPLE 1

### Sputter Deposition of N-Type Thermoelements

A substrate comprising KAPTON (as well as a glass substrate) was positioned 5 inches from both a Sb₂Te₃ (Sb—Te) and a Bi₂Te₃ (Bi—Te) target in a standard sputter deposition chamber. Each target measured 2 inches in diameter. The sputter deposition chamber was evacuated to a pressure of 10⁻⁶ Torr and the system was then filled with purified argon adding to the system sputtering gas pressure (e.g., 3.0 mTorr).

The substrates and the targets were each ion cleaned for 3 to 5 minutes. Plasmas were established above the targets with 30 watts of power being supplied to the Sb—Te target and 20 watts of power to the Bi—Te target. The deposition was carried out with the substrates at ambient temperature. Under these conditions, the deposition rate was 3.5 Å/s. Thus, to deposit a one micron thick film required approximately 47 minutes.

After deposition, the thermoelement thin films were characterized. The thickness was measured with a profilometer. The resistivity and Seebeck coefficient also were determined for the deposited thermoelement thin films, as shown in FIG. 11. Resulting values are provided in Table 1.

TABLE 1
Exemplary Parameters For Deposition On KAPTON*

| | Sb₂Te₃ | Bi₂Te₃ | | | |
|---|---|---|---|---|---|
| Substrate | Target | Target | | | Seebeck |
| Temperature | Power | Power | Growth | Resistivity | Coefficient |
| (° C.) | (Watts) | (Watts) | Rate (Å/s) | (ohm-cm) | (μV/° C.) |
| Ambient | 30 | 20 | 3.5 | 0.0122 | −131 |
| 300 | 30 | 10 | 3.0 | 0.00325 | +158 |

*Sputtering Gas Pressure was 3.0 mTorr; Targets had 2.0 inch diameters; Sb—Te and Bi—Te targets were positioned 5 inches from substrate platform.

### EXAMPLE 2

### Sputter Deposition of p-Type Thermoelements

A substrate comprising KAPTON (as well as a glass substrate) was positioned 5 inches from both a Sb₂Te₃ (Sb—Te) and a Bi₂Te₃ (Bi—Te) target in a standard sputter deposition chamber. Each target measured 2 inches in diameter. The sputter deposition chamber was evacuated to a pressure of 10⁻⁶ Torr and the system was then filled with purified argon adding to the system sputtering gas pressure (e.g., 3.0 mTorr).

The substrates were ion cleaned for 3 to 5 minutes. The substrate temperature was then raised to 300° C. The target surfaces were then ion cleaned for 3 to 5 minutes. Plasmas were established above the targets with 30 watts of power supplied to the Sb—Te target and 10 watts of power to the Bi—Te target. The deposition was carried out with the substrates at 300° C. The deposition rate was 3.0 Å/s. Thus, to deposit a one micron thick film required approximately 55 minutes.

After deposition, the thermoelement thin films were characterized. The thickness was measured with a profilometer. The resistivity and Seebeck coefficient also were determined for the deposited thermoelement thin films. Resulting values are provided in Table 1.

As shown in FIG. 11, the temperature of the substrate effectively determines the Seebeck coefficient for each of the deposited thermoelement thin films in the foregoing examples 1 and 2. The curves in FIG. 11 show the results as the temperature of the substrate was increased from ambient (approximately 20° C.) to a final temperature of about 300° C. for both the resultant p-type material and the resultant n-type material. As shown in FIG. 11, the p-type material having a Seebeck coefficient of +158 and resistivity of 0.00325 ohm-cm was formed when Sb₂—Te₃ and Bi₂—Te₃ were simultaneously sputtered at a temperature of 300° C. using 30 Watts of power to the Sb₂—Te₃ and 10 Watts of power to the Bi₂—Te₃. Conversely, the n-type material, having a Seebeck coefficient of −131 and resistivity of 0.0122 ohm-cm, was formed when Sb₂—Te₃ and Bi₂—Te₃ were simultaneously sputtered at ambient temperature (approximately 20° C.) using 30 Watts of power to the Sb₂—Te₃ and 20 Watts of power to the Bi₂—Te₃.

While the end points are described as “desirable” in FIG. 11, as shown in the respective curves of FIG. 11, each of these materials fluctuated across a wide range of Seebeck coefficients depending on the substrate temperature. Those skilled in the art will recognize that intermediate points to those shown in the curves will produce satisfactory TE elements. Further, while those skilled in the art will recognize that having one thin film with a positive Seebeck coefficient and the other thin film with a negative Seebeck coefficient will generally produce thermoelectric devices having higher power densities, since it is the delta in the Seebeck coefficients between any two thin films that produces the thermoelectric effect, given a sufficient delta between any two thin films the thermoelectric effect is nevertheless expected, and it is therefore not absolutely critical that one be positive and the other be negative. For example, and not meant to be limiting, most metals, e.g., copper, will have a Seebeck coefficient of about 0. Since copper is highly conductive, using copper as one of the thin films will produce a thermoelectric effect, provided that the other thin film has either a sufficiently high or a sufficiently low Seebeck coefficient. Since metals such as copper are generally highly conductive, an effective TE device could be produced using just such an arrangement. Therefore, the use of the terms “n-type” and “p-type” in the present application should be understood to be relative in nature; and any configurations wherein two highly conductive thin films having a sufficient delta in their Seebeck coefficients should be understood to be included in the applicant's use of the terms “n-type” and “p-type.”

### EXAMPLE 3

### Fabrication of a Thermoelectric Array on KAPTON

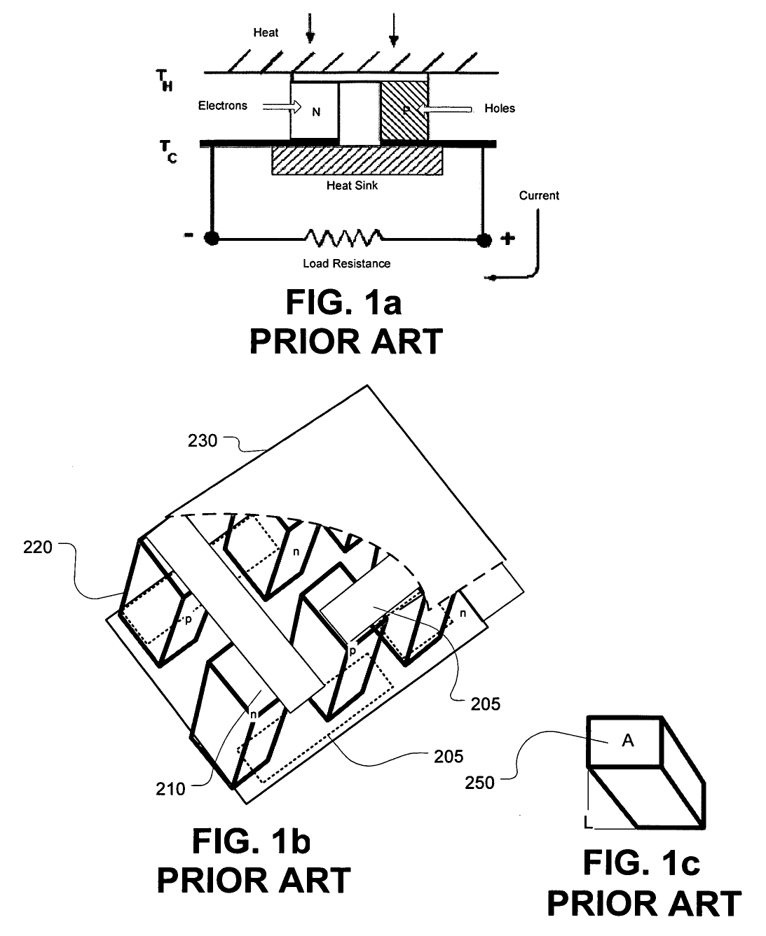

A TE module array like those shown in FIGS. 1a or 9a was fabricated on a substrate comprising KAPTON using masks such as those depicted in FIGS. 12a-12c. The p-type thermoelements were deposited first because they are deposited at 300° C. The n-type thermoelements were deposited next and then the electrically conductive members were deposited.

Specifically, a KAPTON substrate sheet using a mask as shown in FIG. 12b was positioned into a deposition chamber. The mask was securely positioned over the KAPTON sheet using round holes at each end of the mask (see FIG. 12b). Target choices and positioning and other deposition conditions and parameters were as described in Example 2.

Once the desired p-type elements were deposited, the process was stopped and the sputter deposition system opened to replace the p-type mask of FIG. 12b with an n-type mask such as the mask depicted in FIG. 12a. The n-type mask was carefully positioned over the KAPTON sheet, again using the round holes in the mask as guides. Target choices, positioning and other deposition conditions were as described in Example 1.

The process was again stopped once the n-type thermoelements were deposited to replace the n-type mask and with a metallization mask such as the mask depicted in FIG. 12c to form the electrically conductive members. The metallization mask was positioned and secured over the KAPTON sheet using round holes in the mask as guides. By standard sputter deposition procedures, 1.0 μm of aluminum was first deposited, followed by 0.1 μm of nickel.

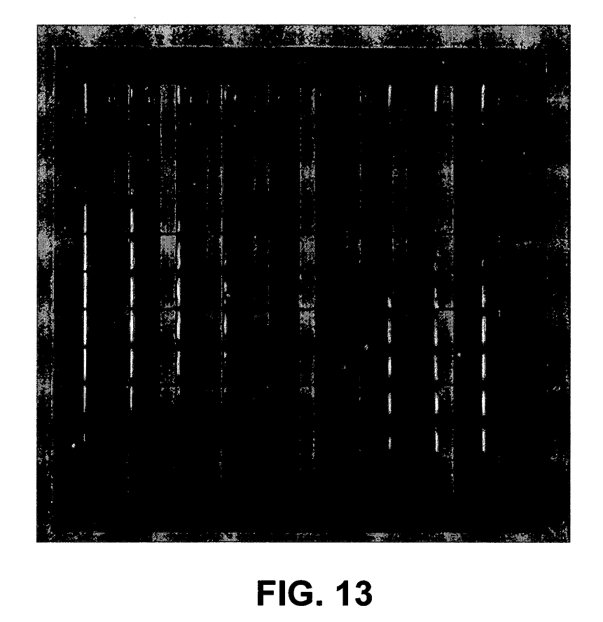

These deposition processes produced an array of p-type and n-type thermoelement modules on a flexible substrate in the configuration shown in FIGS. 2a, 12a-12c, and 13.

The specific templates or masks shown in FIGS. 12a-12c in the foregoing procedure were used to produce two arrays of six thermocouples deposited on two different strips of KAPTON substrate. Such arrays of TE modules were, for example, assembled into a TE power source such as shown in FIG. 5. The fabrication of arrays of six TE modules would allow for production of, e.g., a 25 μW TE power source with a 1.0 V output at a temperature gradient of only 20° C.

### Exemplary Power Sources and Applications for the Same

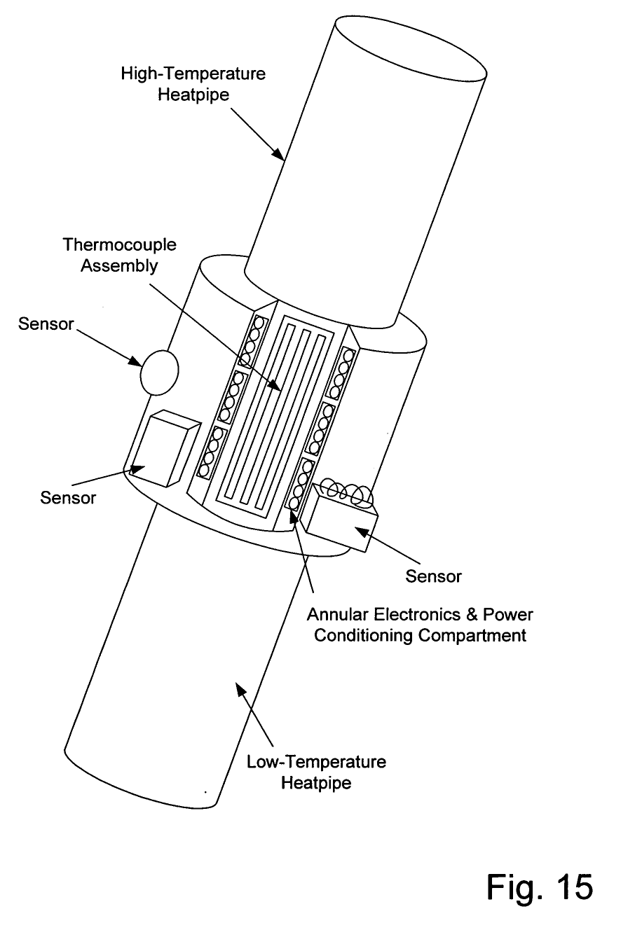

As mentioned above, there are a number of possible embodiments of the disclosed power sources and applications for the same. For example, embodiments of the thermocouple assembly may be used to form an embodiment of the power source as shown in FIG. 15. The TE power source embodiment shown in FIG. 15 may comprise a power source operable, for example, at ambient temperatures. Such a TE power source may include an embodiment of the disclosed thermocouple assembly (TE modules), a heat delivery member and a rejection member (e.g., a low-temperature and a high-temperature heat pipe containing for example condensable fluids), and interfacing electronics including annular electronics, and power conditioning compartments. The heat delivery member and a rejection member may be coupled to the hot and cold junctions or connections of the TE modules. One or both sides of the generator can be heated or cooled by other heat transport methods such as conduction, convection, and/or radiation.

One or more sensors or other low-power applications, for example, may be powered by the disclosed power source. The TE ambient power source embodiment shown in FIG. 15 can produce from power in the range of 100 microwatts to 100 milliwatts, from small ambient differences in temperature (e.g., less than about 5° C., less than about 2° C., or less than about 1° C.). For example, the disclosed power source embodiment may operate in environments where natural temperature differences exist, such as above and below ground surface, water to air temperature differences, skin to air temperature differences or on either side of ductwork that delivers heating, ventilation, and/or air-conditioning in buildings or appliances. Certain embodiments of the disclosed power sources can operate in extreme temperature environments, e.g., as cold as about −100° C. or as hot as about 250° C.

Particular embodiments of the TE power sources as disclosed herein can be used through energy taken directly from the local environment of the application using engineered heat gathering and dissipation components. Such embodiments of the TE power sources can be utilized to power low-power applications such as sensors and the radio frequency transmitters used to send data they generate for a wide range of remote monitoring applications, e.g., building energy management, automotive component controls, agricultural monitoring, security surveillance and wildlife management (avoiding the use of conventional power sources such as batteries and hard-wired alternative power solutions). Such embodiments of the TE power sources and devices provide maintenance free, continuous power for sensors and like applications. Copending U.S. patent application Ser. No. 10/727,062, which is incorporated herein by reference, discusses ambient energy conversion TE power sources.

More specifically, embodiments of the disclosed power sources may be used to power sensors for military weapons proliferation control, battlefield operations, intelligence gathering, safeguards and security activities. Embodiments of the disclosed power sources may be used to power sensors for law enforcement remote monitoring and surveillance, intrusion detection, material accountability, smuggling and like applications. Homeland security may use embodiments of the disclosed TE power sources and devices for intruder sensing, detection, and alarming, border security, chemical and/or biological weapons detection in mailboxes, post offices, public transport, and sensors for buildings. Hospitals may use embodiments of the disclosed TE power sources for pathogen detectors in HVAC systems and corridors, and patient monitoring. The power sources may power sensors for monitoring soil, water delivery, fertilizer and pesticide distribution. They may also be used for tracking threatened and endangered species, body heat activated prosthetics, monitors, hearing aids, communications, convenience, or vanity items, such as, body heat-powered wristwatches, communication equipment, electric jewelry, cell phones, computers, infrared/radar radiation detectors used in a variety of civilian and military applications, humidity, heat, and light sensors, and for safety applications such as personal tracking devices for climbers, backpackers, children, and pets.

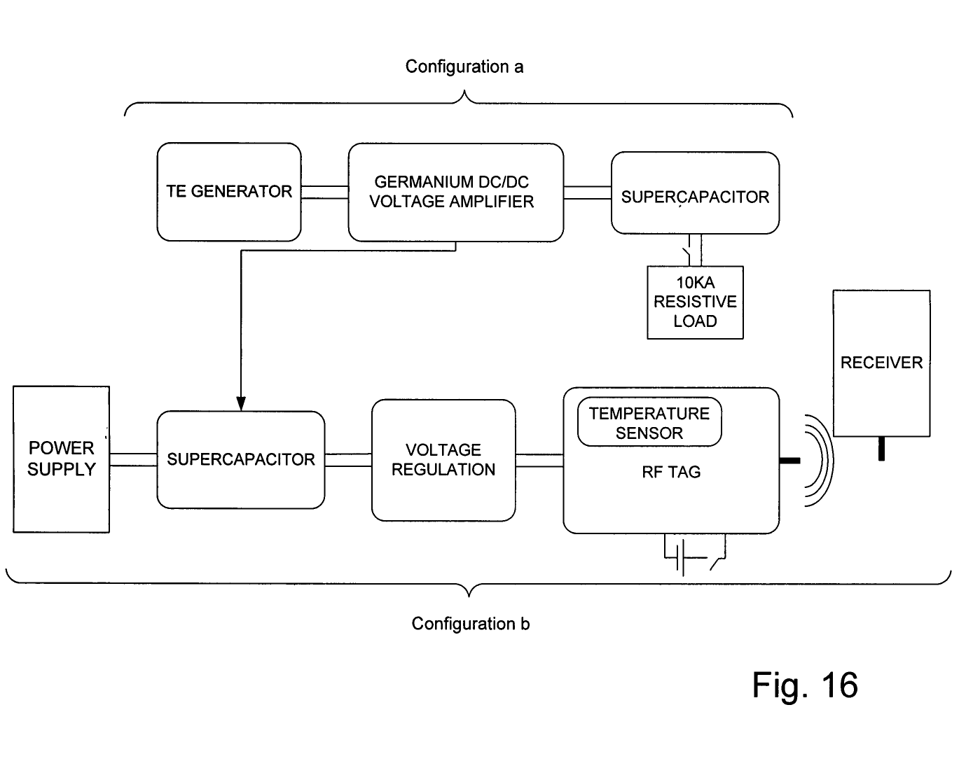

An embodiment of an ambient TE powered sensor system including embodiments of the disclosed TE power sources is disclosed with reference to the system shown in FIG. 16. This assembly comprises a thermoelectric power source (TE generator), a heat management subsystem, power conditioning electronics, one or more sensors, and one or more radio frequency transmitters.

The device disclosed in FIG. 16 was tested as follows. Ambient heat input to the thermoelectric power source (TE Generator) was simulated using a hot-air gun for convenience. Under simulated ambient conditions, the intrinsic voltage output of the thermoelectric power source is a few hundred millivolts. This voltage may be amplified to at least 3.6 V corresponding to the voltage normally supplied by a lithium battery to power the radio frequency components. Because the thermoelectric output voltage may be too low to activate silicon-based electronic power conditioning, a voltage amplifier using germanium transistors was employed to provide a 4.2-V output to the system. A supercapacitor was introduced to store energy so that the radio frequency stage would operate regardless of fluctuations in ambient conditions that affect the output of the thermoelectric converter. A resistive load box simulated the energy drain required to operate the sensor and radio frequency transmitter. This load was manually switched on for periods of about 10 seconds at a frequency representing the transmission cycle of the radio frequency transmitter to drain the equivalent of the total sleep-mode, data acquisition and storage, and transmission energy consumed in each cycle. By respectively heating and cooling the hot and cold shoes of the thermoelectric power source and applying the load periodically as indicated above, the thermoelectric power source was shown to be capable of maintaining capacitor voltage and thereby supply the energy drain of a simulated temperature sensor and radio frequency transmitter that transmitted data every 10 minutes.

The system may further comprise components as shown in Configuration b, of FIG. 16. A conventional regulated laboratory power supply was substituted for the thermoelectric converter and voltage amplifier to permit customizing the sensor and radio frequency subsystem. The sensor and transmitter were adapted from a radio frequency tag that measures, stores, and transmits environmental temperature and shock date. The tag was modified to retain only the temperature measurement function and was reprogrammed to draw less energy than its unmodified counterpart. A voltage regulator circuit was added to prevent draining the capacitor to a voltage that would be too low to maintain microprocessor function. An external switch was added to isolate the battery normally required to operate the radio frequency tag. The tag includes a microprocessor that is programmed before operation. The battery maintains the program whenever the power supply or the thermoelectric modules were not connected. Testing this configuration involved first using the battery to “launch” the program, then isolating it after power was available from the alternative source. A remotely located receiver was used to confirm data transmission. The test sequence using Configuration b of FIG. 16 established that full functionality of the sensor and radio frequency stage could be maintained when the laboratory power supply provided an input to the supercapacitor equivalent to the thermoelectric output characteristics measured with Configuration a of FIG. 16.

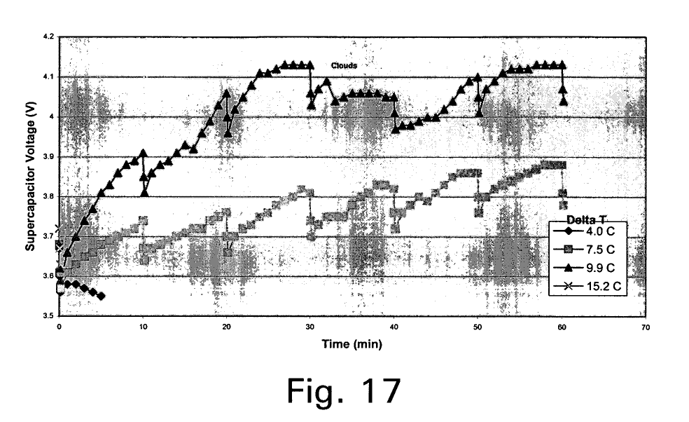

FIG. 17 displays supercapacitor voltage plotted against time measured with Configuration a of FIG. 16 outdoors with solar input to the hot shoe of the thermoelectric generator and a heat sink in earth connected to the cold shoe. This illustrates the ability of the thermoelectric power source to recharge the supercapacitor (i.e., maintain a voltage in excess of 3.6 V) with a temperature difference of greater than about 7° C. across the TE device. At the same time, the capacitor is supplying the demand of the sensor and radio frequency tag system transmitting data every 10 minutes. The voltage steps at 10-minute intervals shown by the successful recharge characteristics represent the approximately 20-mJ energy drain associated with the evaluated load cycle. The 9.9° C. record shows the disclosed TE power source's ability to ride through variability in ambient energy input as illustrated by the slower rate of recharge during a 10-minute interval (between 30 and 40 minutes) when clouds temporarily reduce solar energy input.

In another embodiment, the disclosed TE power source integrates an embodiment of the disclosed thin film thermoelectric modules with heat-gathering and heat-rejecting subsystems that exploit natural temperature differences that exist between, e.g., free air and in-soil environments. Basic components of this system may comprise heat pipes that couple the hot and cold shoes of thermoelectric modules to ambient energy sources existing at different temperatures either side of a barrier or boundary. The boundary between zones of different temperature may comprise, for example, the earth's surface. The upper heat pipe (high-temperature heat pipe) communicates thermal energy harvested from the air to the hot shoe of the TE power source. The lower heat pipe (low-temperature heat pipe) conducts waste thermal energy to the heat sink provided by underlying soil. Clearly, the heat pipes can be composed of a variety of materials and may be formed in various geometries with various dimensions, as would be desirable for particular applications, as known to those persons of ordinary skill in the art.

This embodiment of the disclosed TE power sources produces a useful output bi-directionally, i.e., both when the air is hotter than the soil and vice versa. The double heat pipe is particularly useful if the device is operated in the bi-directional mode, especially when the soil is warmer than the air. In this case, both heat pipes operate as reflux boilers to pump thermal energy through the thermoelectric modules and can exploit gravity-assisted return of internal working fluid to respective evaporator sections in the heat pipes.

An operational mode where energy is harvested from ambient air and conducted downward through the thermoelectric converter to an underground heat sink can be one of many operational modes. This mode allows replacing the upper heat pipe with a thermally absorptive hot shoe extension. However, fluid flow in the lower heat pipe may result from evaporation at the underside of the thermoelectric cold shoe and condensation at the lower extremity of the heat pipe where heat is given up to the soil. Re-circulation of the working fluid in this mode of operation may employ a wick structure on the inside of the pipe to draw the condensate back up to the evaporator region against gravity. A wicking height of about 20 cm can be reached but wicking height is constrained by the physical properties of conventional heat pipe working fluids.

The disclosed thermocouple module comprising many thin-film bismuth telluride thermoelectric elements may be used in this disclosed power source. The thin-film bismuth telluride thermoelectric elements may be deposed on, e.g., a flexible substrate. Such thermoelectric modules may thus be in the form of a rolled up strip of thin-film elements wound on a small reel or bobbin that forms the core of the device.

Such embodiments of the TE power source are readily scalable to higher power levels by increasing the number of thermoelectric elements. For example, many tens of thousands of thermoelectric elements may be incorporated in series and/or series/parallel arrangements to produce device electrical outputs of up to several of watts. The ends of the reel may function as the hot and cold shoes of the thermocouple module. Heat pipes (or other forms of low-temperature and high-temperature members) may be attached at ends of the reel to transfer heat through the thermoelectric module, e.g., from an air side to an in-soil side of the power source. The heat pipes may use, e.g., water as a working fluid, unless freezing conditions are to be accommodated. In this case, methanol or other suitable liquids, such as other alcohols can be used.

The outer surfaces of the air-side heat pipe (or other form of high-temperature member) may be coated with a material having a highly absorptive surface to maximize collection of solar radiation, as well as sensible heat from the ambient air. In certain embodiments, suitable, surface-treated hot shoes are substituted for the air-side heat pipe. This embodiment may reduce an infrared signature of the deployed system. Insulation may be applied to a portion of the lower heat pipe (or other low-temperature member) to prevent heat leakage into it from relatively warmer soil near the surface.

Such an embodiment of the disclosed thermoelectric power source may nominally generate 330-μW of dc power with an output of 100 μA at 3.3 V. A lower voltage device may be assembled with a suitable dc/dc inverter to achieve a 3.3-V output. For example, the inverter may comprise a silicon-based micro-electronic circuit. The TE power source may also incorporate a super-capacitor to provide energy storage to maintain mission functions when the temperature differential across the TE power source is lower than desirable, for example, less than 20° C.

Whereas the TE thermoelements, modules, arrays and power sources as well as the methods for making the same have been described with reference to multiple embodiments and examples, it will be understood that the invention is not limited to those embodiments and examples. On the contrary, the invention is intended to encompass all modifications, alternatives, and equivalents as may be included within the spirit and scope of the invention as defined by the appended claims.

1-36. (canceled)

37. A thermoelectric power source comprising:
a thermoelectric module having at least one thermoelectric couple comprising a sputter deposited thin film p-type thermoelement, a sputter deposited thin film n-type thermoelement positioned adjacent the p-type thermoelement, and an electrically conductive member electrically connecting a first end of the p-type thermoelement with a second end of the n-type thermoelement;
a high-temperature heat pipe connected to a hot connection of the thermoelectric module; and
a low-temperature heat pipe connected to a cold connection of the thermoelectric module.

38. The thermoelectric power source of claim 37, wherein the heat pipes further include a working fluid stored within the heat pipes.

39. The thermoelectric power source of claim 38, wherein the working fluid comprises water, an alcohol, or mixtures thereof.

40. The thermoelectric power source of claim 37, wherein the thermoelectric module comprises multiple thermoelectric couples formed on a flexible substrate.

41. The thermoelectric power source of claim 40, wherein the flexible substrate is wound about a reel.

42. The thermoelectric power source of claim 41, wherein the reel functions as the hot connection and/or the cold connection of the thermoelectric module.

43. The thermoelectric power source of claim 37, wherein the high-temperature heat pipe further includes a coating material on an exterior surface of the heat pipe, the coating material capable of absorbing thermal energy.

44. The thermoelectric power source of claim 43, wherein the coating material on an exterior surface of the heat pipe is capable of absorbing solar radiation.

45. The thermoelectric power source of claim 37, wherein the low-temperature heat pipe further includes insulation on an exterior surface of the heat pipe to reduce transfer of thermal energy from outside the low-temperature heat pipe to inside the low-temperature heat pipe.

46. A TE power source comprising:
a thin film TE module comprising multiple thin film TE p-type and n-type elements formed on a flexible substrate;
a reel having a first end and a second end and about which the flexible substrate is wound;
a low-temperature member thermally connected to the first end of the reel; and
a high-temperature connected to the second end of the reel, wherein the low-temperature and high-temperature members transfer heat to the and from the TE module.

47. The TE power source of claim 46, wherein the low-temperature member and the high-temperature member comprise a first and a second heat pipe, respectively.

48. The TE power source of claim 46, wherein the heat pipes further include a working fluid within the heat pipes.

49. The TE power source of claim 48, wherein the working fluid comprises water, an alcohol, or mixtures thereof.

50. The TE power source of claim 46, wherein the thin film TE p-type and n-type elements comprise sputter deposited BiₐTe_{b} where a is about 2 and b is about 3.

51. The TE power source of claim 48, wherein the working fluid in the heat pipes is re-circulated within the heat pipes.

52. The TE power source of claim 46, wherein the TE power source can generate and maintain a voltage of equal to or greater than about 3.6 V with a temperature difference across the TE module of greater than about 7° C.

53. The TE power source of claim 46, wherein the TE power source can operate in temperature environments of greater than about 100° C.

54. The TE power source of claim 46, wherein the TE power source can operate in temperature environments of less than about −100° C.

55. The TE power source of claim 46, wherein the TE power source can operate in temperature environments of greater than about 250° C.
